(19) United States
(12) Patent Application Publication
(10) Pub. No.: US 2002/0153903 A1
(43) Pub. Date: Oct. 24, 2002

(54) Device and method for testing and calibrating multi-meters in a cathode ray tube production line

(75) Inventors: David Allen Murtishaw, Sun City, CA (US); David Michael Cataldo, Poway, CA (US); Walter A. Brendel JR., San Diego, CA (US)

Correspondence Address: STEVEN L. NICHOLS, RADER, FISHMAN & GRAVER PLLC, 10653 S. RIVER FRONT PARKWAY, SUITE 150, SOUTH JORDAN, UT, 84095, US

(73) Assignee: Sony Corporation and Sony Electronics Inc.

(21) Appl. No.: 09/839,282

(22) Filed: Apr. 20, 2001

(51) Int. Cl. G01R 35/00

(52) U.S. Cl. 324/601

(57) ABSTRACT

A jig can be used to site-test the accuracy of multi-meters that are used to measure resistances in a cathode ray tube production line without having to remove those multi-meters from the production line or ship them to a third party service provider for the testing. The jig is a box of electronics that includes a variety of known resistance loads that can be selected and then measured by a multi-meter to test and/or calibrate that meter. The jig includes a number of known resistance loads, a device for selecting a particular resistance load and electric contacts for connecting a multi-meter to the jig so that the meter can measure the selected and known resistance load. By comparing the measured and known resistance values, the accuracy of the multi-meter is tested.

### FIELD OF THE INVENTION

The present invention relates to the field of cathode ray tube manufacture. More specifically, the present invention relates to a method and device for testing and calibrating multi-meters used to measure resistance in a cathode ray tube production line. The present invention provides a jig with a variety of known resistance loads that can be selected and then measured by a multi-meter to test and/or calibrate that meter.

### BACKGROUND OF THE INVENTION

Cathode ray tubes (“CRTs”) are well known in modern society. The CRT is the principal component in such common devices as television sets and computer and video monitors. As shown in FIG. 1, a CRT (100) typically includes a relatively flat display portion (101) (upper portion as seen in FIG. 1). When one is watching television or looking at a computer monitor, that person is looking at the flat display portion (101) of a cathode ray tube. Below the display portion (101) is a funnel portion (102) that narrows into the “neck” of the CRT.

During manufacture, layers of carbon material are coated on the interior of the CRT funnel (102). Also, an electro-luminescent material such as phosphorus is coated over the display portion (101) of the CRT. The display portion (101) is then joined to the funnel (102) using a glass paste compound known as frit. A bead of frit is distributed around the interface between the funnel (102) and the display portion (101). The frit is then cured or hardened to form an airtight seal between the display portion (101) and the funnel (102). This seal may be referred to as a frit seal (103).

An electron gun is then placed at the end of the CRT's “neck” (102). When the CRT is operated, an electromagnetic yoke (104) placed around the funnel (102) creates an electromagnetic field that varies over time. This electromagnetic field deflects the stream of electrons emitted from the electron gun in a regular scanning pattern, causing the electron stream to scan in horizontal lines across the surface of the display portion (101).

Where the stream of electrons hits the electro-luminescent material, the electro-luminescent material emits light. Thus, by rapidly switching the electron stream on and off, or by varying the power of the electron stream as it sweeps across the display portion of the CRT, an image can be formed in the light emitted by the electro-luminescent material. This is the general principle on which CRTs operate.

Control circuitry (105) is also added to the CRT (100) to drive the yoke (104) and the electron gun. The electron gun is driven in response to the incoming video signal that defines the images to be created by the CRT (100).

During production of a CRT, it is necessary to measure the resistance of some of the components of the CRT in order to assure quality and proper operation of the finished product. In particular, the resistance of the carbon material applied inside the funnel (102) may need to be checked to assure the quality of the CRT being produced.

These resistances are measured using, for example, a multi-meter (110). Multi-meters are well known devices used for measuring basic electrical quantities such as resistance, current, voltage, etc. The multi-meter (110) includes a pair of test leads (112, 113) that are connected across the CRT component whose resistance is to be measured. The multi-meter (110) is then activated and displays the measured resistance on a display device (111). In this way, the resistance of any component can be quickly measured to confirm that it meets the requirements of the CRT being assembled.

The accuracy of this measurement and the consequent assurance that the CRT components meet operating requirements is only as reliable as the multi-meter used. Consequently, it becomes necessary on a periodic basis, usually annually, to remove the multi-meters used in the CRT production line and have those meters tested for accuracy and, if necessary, recalibrated. This is typically done be sending the meters to a third-party service provider who tests, calibrates and certifies the accuracy of the multi-meters.

Unfortunately, removing the multi-meters from service on the CRT production line interrupts the flow of CRT production. Additionally, sending multi-meters out for testing and calibration is an unnecessary expense if the meters are still functioning properly.

Consequently, there is a need in the art for a device and method for testing and calibrating multi-meters used to measure resistance in a cathode ray tube production line without requiring that the meters be removed from service in the cathode ray tube production line.

### SUMMARY OF THE INVENTION

The present invention meets the above-described needs and others. Specifically, the present invention provides a device and method for testing and calibrating multi-meters used to measure resistance in a cathode ray tube production line without requiring that the meters be removed from service in the cathode ray tube production line.

Additional advantages and novel features of the invention will be set forth in the description which follows or may be learned by those skilled in the art through reading these materials or practicing the invention. The advantages of the invention may be obtained and achieved through the means recited in the attached

The present invention may be embodied and described as a jig for testing the accuracy of a resistance meter used in a cathode ray tube manufacturing process. In a preferred embodiment, the jig includes at least one known resistance load; and electrical contacts for connecting the meter to the jig so that the meter can measure the resistance of the resistance load.

More preferably, the jig actually provides a number of known resistance loads; and the jig further includes a control device for selecting one of the resistance loads and bringing that selected resistance load into a circuit with the electrical contacts. The control device for selecting the resistance load may be a dial that moves a switch to make a connection to the selected resistance load.

Preferably, the exterior of the jig has a listing of resistance values that correspond to the available resistance loads in the jig. The listing of resistance values is associated with the control device for selecting a resistance load to guide a user in selecting a particular resistance load with the control device.

The resistance load or loads in the jig can be provided with resistors or a combination of resistors.

The present invention also encompasses the methods of making and using the jig described above. More specifically, the present invention encompasses a method of using a testing jig for testing the accuracy of a resistance meter used in a cathode ray tube manufacturing process, where the testing jig provides a known resistance load. The method is performed by connecting the meter to the testing jig; measuring a resistance of the resistance load provided by the jig with the meter; and determining the accuracy of the meter by comparing the resistance value measured by the meter with the known resistance value of the resistance load.

The preferred method may also include any or all of the following steps: (1) bringing the jig to a location where the meter is used in the cathode ray tube manufacturing process so that the meter can be tested with the jig; (2) performing the testing of the meter with the jig on a regular basis; and (3) performing the testing of the meter with the jig whenever there is reason to suspect a malfunction of the meter. To better ensure the accuracy of the meter being tested, the method of the present invention may also include repeatedly testing the meter against two or more known resistance loads provided by the jig to further verify accurate operation of the meter.

### BRIEF DESCRIPTION OF THE DRAWINGS

The accompanying drawings illustrate preferred embodiments of the present invention and are a part of the specification. Together with the following description, the drawings demonstrate and explain the principles of the present invention.

FIG. 1 is an illustration of a conventional cathode ray tube and multi-meter used to introduce the present invention.

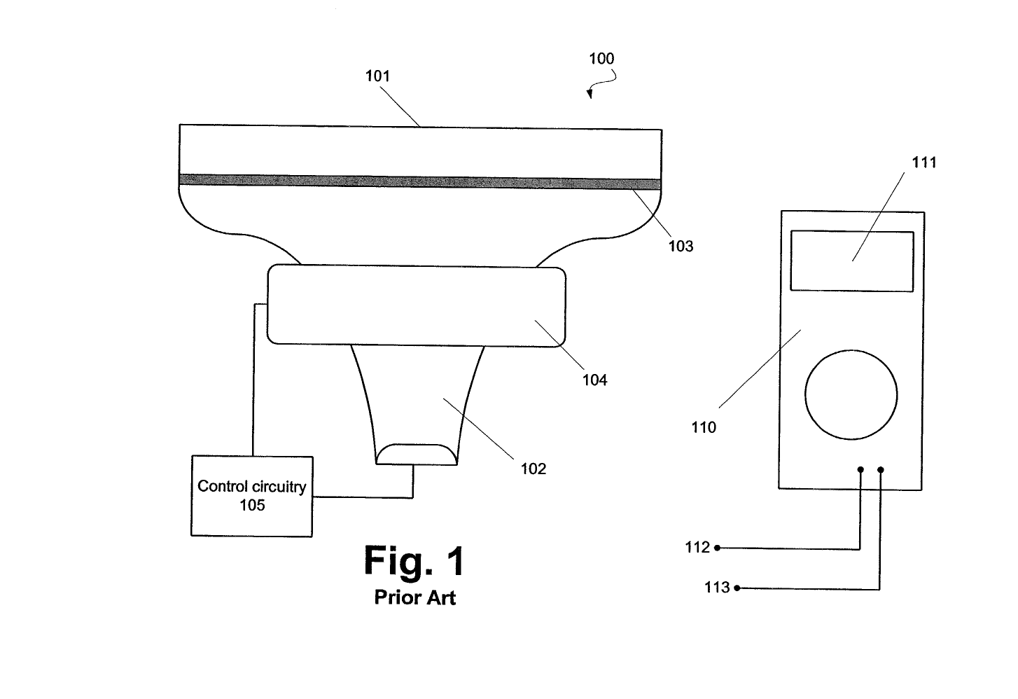

FIG. 2 is an illustration of a preferred embodiment of the exterior of a multi-meter testing jig according to the present invention.

FIG. 3 is a circuit diagram illustrating a preferred embodiment of the interior of a multi-meter testing jig according to the present invention.

FIG. 4 is an illustration of the jig shown in FIG. 3 connected to a multi-meter to test the multi-meter according to the principles of the present invention.

FIG. 5 is a flow chart illustrating a preferred embodiment of a method of using the jig of FIGS. 3 & 4 according to the principles of the present invention.

Throughout the drawings, identical elements are designated by identical reference numbers.

### DETAILED DESCRIPTION OF THE PREFERRED EMBODIMENTS

Stated in broad general principle, the present invention provides a device and method for testing the accuracy of, and calibrating, multi-meters that are used to measure resistances in a cathode ray tube production line without having to remove those multi-meters from the production line or ship them to a third party service provider for the testing. The device of the present invention is a jig, i.e., a box of electronics, that includes a variety of known resistance loads that can be selected and then measured by a multi-meter to test and/or calibrate that meter. Both the device and method of the present invention will be explained in detail below with reference to the appended drawings.

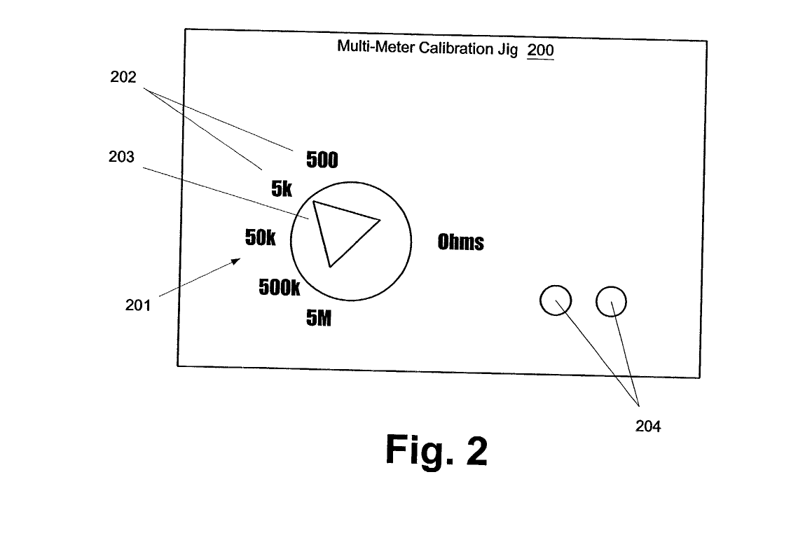

FIG. 2 illustrates an exterior of a preferred embodiment of the jig of the present invention. As mentioned above and as used herein, a “jig” is a device that embodies known parameters which can be used to test or guide other equipment or processes. In the context of the present invention, the jig (200) is a box of electronic components that provide known resistance loads. By selecting several specific resistances and measuring those known resistances with the multi-meter being tested, the accuracy of the multi-meter within a given tolerance can be confirmed.

As shown in FIG. 2, the exterior of the jig (200) of the present invention preferably includes some device for selecting one of several resistance loads that the jig (200) can provide. In the exemplary jig (200) of FIG. 2, this selection device is a dial (203). Around the dial (203), are a number of listed resistance values (e.g., 202) in Ohms. By moving the dial (203) to point at a particular listed resistance value, that indicated resistance load will then be provided by the jig (200).

While a dial (203) is illustrated in FIG. 2, any other device or means for selecting one of several specified resistance loads within the jig (200) is within the scope of the present invention. For example, a keypad with buttons which each correspond to a particular resistance load could also be implemented in the jig of the present invention, the button being pressed representing the selected resistance load.

The exterior of the jig (200), as shown in FIG. 2, also includes a pair of electrical contacts (204). These contacts may be ports, electrical contact pads, etc. The two test leads of the multi-meter being tested are electrically connected to the jig (200) using the two contacts (204) of the jig. The multi-meter can then be used to test the selected resistance load being provided by the jig. This process will be illustrated and explained in greater detail below.

The precise form of the electrical contacts (204) may be chosen to facilitate easy connection with the test leads of the multi-meter. For example, if the test leads of the multi-meter are bare wires, the contacts (204) may be pads that the meter leads can be brought into contact with. The contacts (204) may, alternatively, be conductive posts or screws to which the lead wires are connected. If the test leads of the multi-meter are probes of a specific shape, the contacts (204) may be ports shaped and sized to receive the probe tips of the multi-meter.

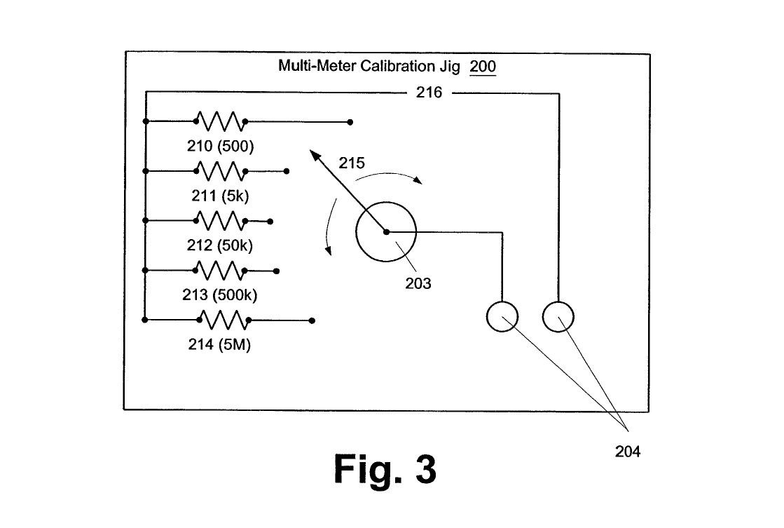

FIG. 3 is a circuit diagram showing the interior of the jig (200) of the present invention. As shown in FIG. 3, the jig (200) includes a number of resistors (210-214). Each resistor (210-214) has a specific, known resistance value. In the example of FIG. 3, five resistors (210-214) are provided in the jig (200). Resistor (210) has a resistance value of 500 Ohms. Resistor (211) has a resistance of 5,000 Ohms. Resistor (212) has a resistance of 50,000 Ohms. Resistor (213) has a resistance of 500,000 Ohms. Resistor (214) has a resistance of 5,000,000 Ohms. This number of resistors and these resistance values are merely exemplary, and the jig of the present invention is not limited to this embodiment.

A first end of each of the resistors (210-214) is electrically connected to one of the contacts (204). The other contact is connected to a switch (215) that can be moved to connect to the second end of any of the resistors (210-214). The motion of the switch (215) is indicated by the arrows shown in FIG. 3. By moving the switch (215), any of the resistors (210-214) can be brought into a circuit with two electrical contacts (204). In the preferred embodiment, the dial (203) of the jig (200) is used to move the switch (215) between the available resistors (210-214).

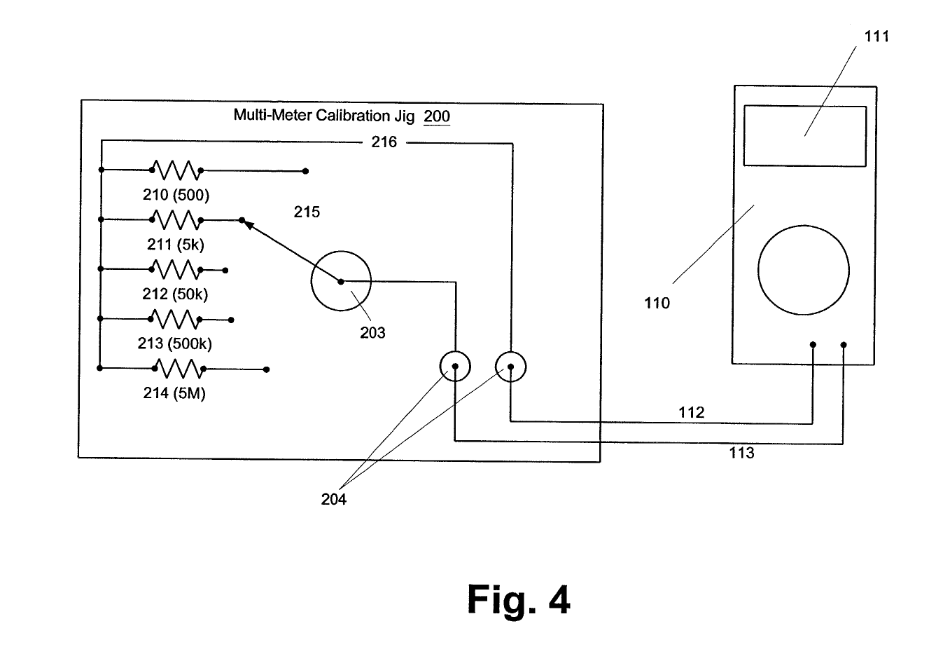

FIG. 4 illustrates the use and operation of the jig (200) of the present invention. In the example of FIG. 4, the switch (215) has been moved to select resistor (211) (5 k Ohms) as the resistance load the jig (200) will provide. Consequently, the arm of the switch (215) is brought into electrical contact with the available end of the resistor (211) as shown in FIG. 4. In this position, the switch (215) completes a circuit within the jig (200) that runs from one of the electrical contacts (204), through the resistor (211) and back to the other of the electrical contacts (204).

As shown in FIG. 4, the multi-meter (110) being tested is then connected to the jig (200). This is done by connecting the test leads (112, 113) of the multi-meter to the electrical contacts (204) of the jig (200). The meter (110) is then set to measure the resistance of the resistor (211). Knowing that the resistor (211) has a resistance value of 5,000 Ohms, the accuracy of the meter (110) can be determined by comparing the meter's measurement of the resistance of resistor (211) to the known value of 5,000 Ohms.

The resistance value of the resistor (211) is measured by the meter (110) and displayed on the meter's display (111). If the measured value is 5,000 Ohms, plus or minus an acceptable tolerance, the multi-meter (110) is known to be operating properly.

To further test the multi-meter (110), one or more additional resistance loads can be selected on the jig (200) and measured by the multi-meter (110). If the multi-meter accurately measures a number of different known resistance values, within acceptable tolerances, the multi-meter (110) has been shown to be operating properly and need not be removed from the production line and sent out for testing and calibration.

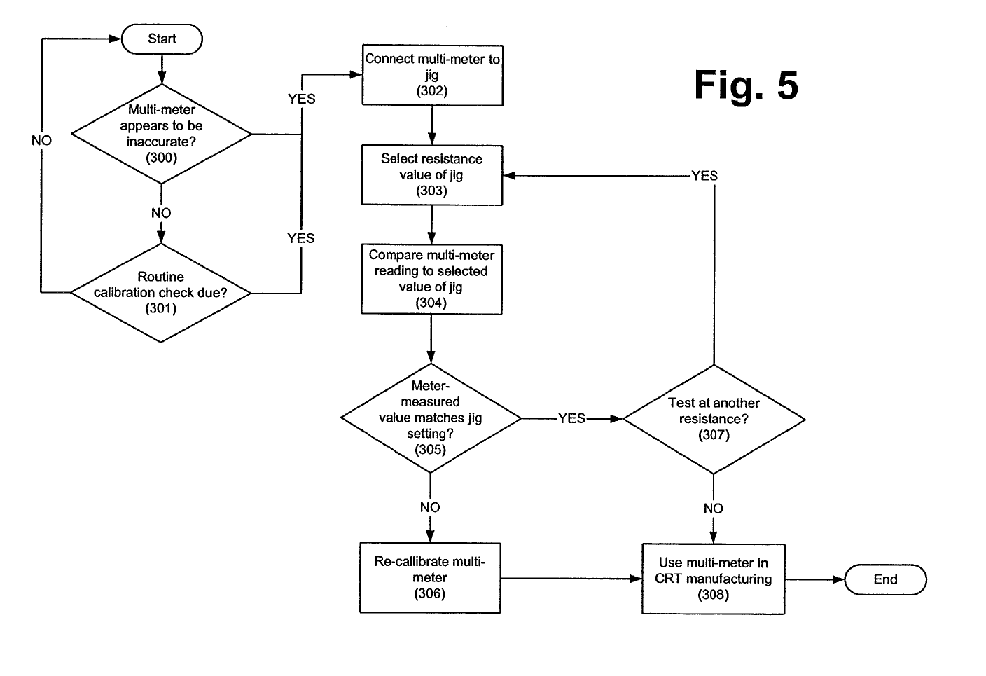

FIG. 5 is a flowchart that illustrates the method of using the jig described above according to the present invention. The methods of making and using the jig are within the scope of the present invention.

As shown in FIG. 5, the method of the present invention can begin by observing the multi-meters used in the CRT production line. If any multi-meter appears to be malfunctioning (300), the meter can be tested (302) without the need to remove it from service in the production line and send it out for testing. This is possible because the jig of the present invention can be readily brought to where the multi-meter is in service and used to test the meter. Testing the meter with the jig of the present invention requires only minimal technical training and can be readily performed by those maintaining the operation of the CRT production line.

If there is no evidence or reason to believe that the meter (300) is malfunctioning, the meter should still be tested for accuracy on a regular basis (301). For example, the meter may be tested annually.

In either case, the meter is tested by connecting it to the jig of the present invention in the manner described above (302). Next, a known resistance value is selected as the resistance load to be provided by the jig (303). The resistance load as measured by the multi-meter is then compared to the known resistance value selected within the jig (304).

If the measured resistance value matches the known resistance value within an acceptable tolerance (305), then the accuracy of the multi-meter has been verified. If the measured and known resistance values do not match, the meter is no longer functioning accurately and can be removed from service for further testing and recalibration (306).

Even if the measured resistance value matches the known resistance value within an acceptable tolerance (305), it may be desirable to further confirm the accuracy of the meter (307). This is done be selecting another known resistance value on the jig and repeating the measurement and comparison process (303-305).

Once the meter is either verified as accurate to the extent desired, or shown to be inaccurate and accordingly repaired, the meter can be used in the CRT manufacturing process (308). Thus, the meters being used are maintained so as to consistently function accurately.

With the present invention, those operating the CRT production line can be continually assured that the multi-meters used to measure resistance values on the production line are functioning accurately. The production line need not be interrupted to remove meters from service and send them out for periodic testing and calibration. Only those meters that are shown to be inaccurate are sent for repair, thereby minimizing unnecessary expenses in maintaining the multi-meters. Consequently, the jig of the present invention and its method of use provide a number of important advantages in the production of cathode ray tubes.

The preceding description has been presented only to illustrate and describe the invention. It is not intended to be exhaustive or to limit the invention to any precise form disclosed. Many modifications and variations are possible in light of the above teaching.

The preferred embodiment was chosen and described in order to best explain the principles of the invention and its practical application. The preceding description is intended to enable others skilled in the art to best utilize the invention in various embodiments and with various modifications as are suited to the particular use contemplated. It is intended that the scope of the invention be defined by the following claims.

What is claimed is:

1. A jig for testing the accuracy of a resistance meter used in a cathode ray tube manufacturing process, said jig comprising:
at least one known resistance load; and
electrical contacts for connecting said meter to said jig so that said meter can measure a resistance of said resistance load.

2. The jig of claim 1, wherein said at least one known resistance load comprises a plurality of known resistance loads; and said jig further comprises a control device for selecting one of said plurality of known resistance loads and bringing that selected resistance load into a circuit with said electrical contacts.

3. The jig of claim 2, wherein said control device for selecting a resistance load comprises a dial that moves a switch to make a connection to said selected resistance load.

4. The jig of claim 2, wherein an exterior of said jig has a listing of resistance values that correspond to said plurality of known resistance loads in said jig, said listing of resistance values being associated with said control device to guide a user in selecting a particular resistance load with said control device.

5. The jig of claim 1, wherein said least one known resistance load is a resistor.

6. The jig of claim 2, wherein said plurality of known resistance loads is a corresponding plurality of resistors.

7. A method of using a testing jig for testing the accuracy of a resistance meter used in a cathode ray tube manufacturing process, where said testing jig provides a known resistance load, said method comprising:
connecting said meter to said testing jig;
measuring a resistance of said resistance load provided by said jig with said meter; and
determining an accuracy of said meter by comparing said resistance value measured by said meter with a known resistance value of said resistance load.

8. The method of claim 7, further comprising bringing said jig to a location where said meter is used in said cathode ray tube manufacturing process so that said meter can be tested with said jig.

9. The method of claim 7, further comprising performing said testing of said meter with said jig on a regular basis.

10. The method of claim 7, further comprising performing said testing of said meter with said jig whenever there is reason to suspect a malfunction of said meter.

11. The method of claim 7, wherein said known resistance load comprises a plurality of known resistance loads; and said method further comprises selecting one of said plurality of known resistance loads and bringing that selected resistance load into a circuit with said electrical contacts.

12. The method of claim 11, further comprising repeatedly testing said meter against two or more known resistance loads provided by said jig to further verify accurate operation of said meter.

13. The method of claim 11, wherein said selecting one of said plurality of known resistance loads comprises moving a switch with a dial to make a connection to said selected resistance load.

14. The method of claim 11, further comprising providing on an exterior of said jig a listing of resistance values that correspond to said plurality of known resistance loads in said jig, said listing of resistance values being associated with a control device to guide a user in selecting a particular resistance load with said control device.

15. The method of claim 7, wherein said resistance load provided by said jig is provided by a resistor in said jig.

16. A system for testing the accuracy of a resistance meter used in a cathode ray tube manufacturing process with a testing jig, said system comprising:
means for providing a known resistance load with said jig; and
means for connecting said meter to said testing jig so as to measure a resistance of said resistance load provided by said jig with said meter.

17. The system of claim 16, further comprising means for determining an accuracy of said meter by comparing said resistance value measured by said meter with a known resistance value of said resistance load.

18. The system of claim 16, further comprising means for bringing said jig to a location where said meter is used in said cathode ray tube manufacturing process so that said meter can be tested with said jig.

19. The system of claim 16, further comprising:
means for providing a plurality of known resistance loads with said jig; and
means for selecting one of said plurality of known resistance loads and bringing that selected resistance load into a connection with said meter.

20. The system of claim 19, further comprising means for selecting one of said plurality of known resistance loads comprises a switch controlled by a dial.

21. The system of claim 19, further comprising means on an exterior of said jig for listing available resistance values that correspond to said plurality of known resistance loads in said jig, said listing of resistance values being associated with a control device to guide a user in selecting a particular resistance load with said control device.

22. The system of claim 16, wherein said means for providing a known resistance load with said jig; comprises a resistor.
